(19) United States
(12) Patent Application Publication
(10) Pub. No.: US 2024/0397800 A1
(43) Pub. Date: Nov. 28, 2024

(54) TRANSPARENT DISPLAY PANEL AND DISPLAY DEVICE

(71) Applicant: LG DISPLAY CO., LTD., Seoul (KR)

(72) Inventors: JongHyun Park, Paju-si (KR); SangMoo Song, Paju-si (KR)

(73) Assignee: LG DISPLAY CO., LTD., Seoul (KR)

(21) Appl. No.: 18/674,155

(22) Filed: May 24, 2024

(30) Foreign Application Priority Data
May 25, 2023 (KR) 10-2023-0067802

(51) Int. Cl. H10K 59/80; G02B 27/01; H10K 59/121; H10K 102/00

(52) U.S. Cl. CPC H10K 59/879; H10K 59/121; H10K 59/873; G02B 2027/0141; G02B 2207/101; H10K 2102/3031

(57) ABSTRACT

A transparent display device can include a display area including a transmissive area and a non-transmissive area, a plurality of emission areas disposed in the non-transmissive area, the plurality of emission areas being configured to emit light, and at least one first optical pattern disposed in the transmissive area.

### CROSS-REFERENCE TO RELATED APPLICATIONS

This application claims priority to Korean Patent Application No. 10-2023-0067802, filed on May 25, 2023, the entire contents of which are hereby expressly incorporated by reference into the present application.

### BACKGROUND

### Technical Field

The present disclosure relates to a transparent display panel and a display device including the same. In more detail, the present disclosure relates to a transparent display panel and a display device including the same, which are capable of improving transparency while minimizing a diffraction phenomenon by an external light source and increasing concentrating efficiency of external light that passes through the transparent display panel.

### Discussion of the Related Art

With advancement in information-oriented societies, demands for display devices that display images have increased in various forms. Recently, various types of display devices such as a liquid crystal display (LCD) device, a plasma display panel (PDP) device, a Quantum dot Light Emitting Display (QLED), and an organic light emitting display (OLED) device have been widely utilized.

In particular, the organic light emitting display devices are attracting attention as next-generation display devices because they are not only advantageous in terms of power consumption due to low-voltage operation, but also in terms of color reproduction, response speed, viewing angle, and contrast ratio.

In recent years, there has been active research on display devices that have a transmissive area to allow external light to pass through them, such that a background scene located behind the display device or objects or images located on the rear surface of the display device can be viewed through the display device.

### SUMMARY OF THE DISCLOSURE

The present disclosure is directed to providing a transparent display panel and a display device that substantially obviates one or more problems due to limitations and disadvantages of the related art.

An aspect of the present disclosure is directed to providing a transparent display panel and a display device that can minimize a diffraction phenomenon of light and reduce haze to improve clarity, visibility, and readability of the display device.

Another aspect of the present disclosure is directed to providing a transparent display panel and a display device capable of improving transparency by increasing concentrating efficiency of external light when external light outside of or behind the display device passes through the display device.

Another aspect of the present disclosure is directed to providing a transparent display panel and a display device capable of realizing ESG (Environment/Social/Governance) by increasing the lifespan of display devices and reducing the generation of greenhouse gases due to the manufacturing process for producing a display device.

Additional advantages and features of the disclosure will be set forth in part in the description which follows and in part will become apparent to those having ordinary skill in the art upon examination of the following or can be learned from practice of the disclosure. Other benefits of the disclosure can be realized and attained by the structure particularly pointed out in the written description and claims hereof as well as the appended drawings.

To achieve these and other advantages and in accordance with the purpose of the disclosure, as embodied and broadly described herein, there is provided a transparent display panel including a display area including a transmissive area and a non-transmissive area, a plurality of emission areas provided in the non-transmissive area, and at least one first optical pattern disposed in the transmissive area.

The first optical pattern can be disposed to correspond to a center of the transmissive area.

In another aspect of the present disclosure, there is provided a transparent display panel further including a plurality of second optical patterns disposed at the border area of the transmissive area.

A height of the plurality of second optical patterns can be lower than a height of the first optical pattern.

A width of the plurality of second optical patterns can be narrower than a width of the first optical pattern.

The emission areas include a light emitting device layer formed by stacking a first electrode, a light emitting layer, and a second electrode, and an encapsulation layer disposed on the light emitting device layer. The first optical pattern and the plurality of the second optical pattern can be disposed on the encapsulation layer.

The transparent display can further include an optical insulating layer configured to cover the first optical pattern and the plurality of second optical patterns on the encapsulation layer.

In another aspect of the present disclosure, at least some of the plurality of second optical patterns of the transparent display panel have separation different distances from an edge of the first optical pattern.

At least one of the plurality of second optical patterns overlaps at least partially a border of the non-transmissive area adjacent an edge of the transmissive area.

In another aspect of the present disclosure, there is a display device including a transparent display panel configured to have a transmissive area and a non-transmissive area in a display area of a first substrate and a second substrate facing each other and a tempered glass disposed on the transparent display panel, in which a first optical pattern is disposed in a center of the transmissive area, and in which a plurality of second optical pattern are spaced apart from the first optical pattern and disposed at a border area of the transmissive area.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure. In the drawings:

FIG. 1 illustrates a display device according to one or more embodiments of the present disclosure;

FIG. 2 is a circuit diagram of a sub-pixel illustrated in FIG. 1 according to an embodiment of the present disclosure;

FIG. 3 is a plan view illustrating a plurality of pixels according to one embodiment of an area A of display panel illustrated in FIG. 1 according to an embodiment of the present disclosure;

FIG. 4 is cross-sectional view taken along line I-I′ of FIG. 3 according to an embodiment of the present disclosure;

FIG. 5 is a perspective view illustrating one example of the first optical pattern according to an embodiment of the present disclosure;

FIG. 6 illustrates a stacked structure according to one example of the B region of FIG. 4 according to an embodiment of the present disclosure;

FIG. 7 is a plan view illustrating a plurality of pixels according to another embodiment of the area A of the display device illustrated in FIG. 3 according to an embodiment of the present disclosure;

FIG. 8 is cross-sectional view taken along line II-II′ of FIG. 7 according to an embodiment of the present disclosure;

FIG. 9 is a plan view illustrating a plurality of pixels according to another embodiment of the second optical pattern illustrated in FIG. 7 according to an embodiment of the present disclosure;

FIG. 10 is cross-sectional view taken along line III-III′ of FIG. 9 according to an embodiment of the present disclosure; and

FIGS. 11A to 11C are diagrams illustrating examples of display devices with a transparent display panel according to one or more embodiments of the present disclosure.

### DETAILED DESCRIPTION OF THE EMBODIMENTS

Hereinafter, the aspects of the present disclosure will be described in detail with reference to the accompanying drawings. The following aspects are provided by way of example so that spirit of the present disclosure can be sufficiently conveyed to those skilled in the art. Thus, the present disclosure can be embodied in different forms and should not be construed as limited to the aspects set forth herein.

A size and a thickness of device disclosed in the drawings, can be exaggerated for convenience. The scale of the components shown in the drawings are merely an example, thus the present disclosure is not limited to the illustrated scales. Like reference numerals refer to like elements throughout.

In the following description, when the detailed description of the relevant technology is determined to unnecessarily obscure the important point of the present disclosure, the detailed description will be omitted.

In a situation where “comprise,” “have,” and ‘include’ described in the present disclosure are used, another part can be added. The terms of a singular form can include plural forms unless referred to the contrary.

In describing a positional relationship, for example, when a position relation between two parts is described as “on,” “over,” “under,” and “next,” one or more other parts can be disposed between the two parts unless ‘just’ or ‘direct’ is used. The spatially relative terms “below,” “beneath,” “lower,” “above,” “upper,” and the like can be used to facilitate the description of the relationship of one element (or component) to another element (or component) as shown in the drawings. The spatially relative terms should be understood to include different orientations of an element in use or operation in addition to the orientations shown in the drawings. For example, an element described as “below” or “beneath” another element can be placed “above” another element when the elements shown in the drawings are inverted. Thus, the exemplary term “below” can include both downward direction and upward direction.

It will be understood that, although the terms “first,” “second,” “A,” “B,” “(a),” “(b),” etc. can be used herein to describe various elements of the present disclosure. These terms are only used to distinguish one element from another and the nature, sequence, order, or number of these elements should not be limited by these terms.

In assigning reference numerals to the components in each drawing, the same component can have the same numeral as far as possible, even if it is shown in different drawings. In addition, when the detailed description of the relevant technology is determined to unnecessarily obscure the important point of the present disclosure, the detailed description will be omitted.

Features of various aspects of the present disclosure can be partially or totally coupled to or combined with each other, and can be variously inter-operated with each other and driven technically as those skilled in the art can sufficiently understand. The aspects of the present disclosure can be carried out independently from each other or can be carried out together with a co-dependent relationship.

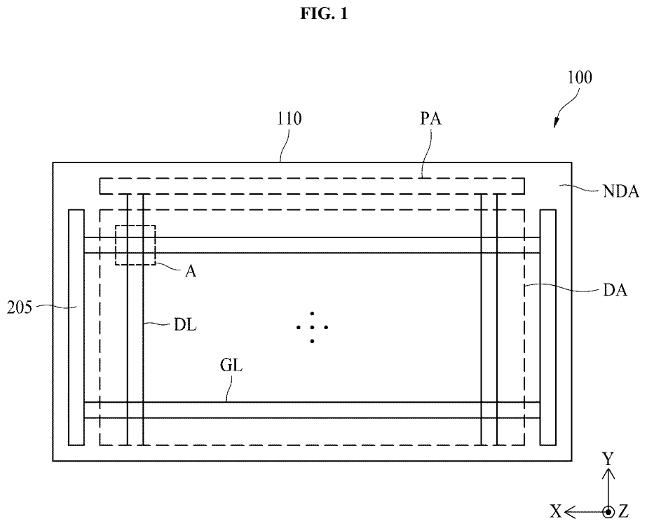

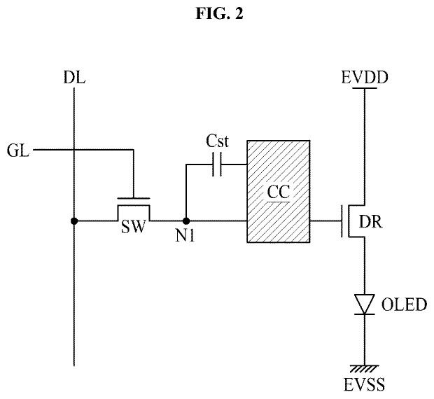

Hereinafter, with reference to the accompanying drawings and embodiments, a display device according to the present disclosure is described as follows. FIG. 1 is a illustrates a display apparatus according to an embodiment of the present disclosure, and FIG. 2 is circuit diagram of a sub-pixel illustrated in FIG. 1 according to an embodiment of the present disclosure.

In FIGS. 1 and 2, an X axis represents a direction parallel to a gate line, a Y axis represents a direction parallel to a data line, and a Z axis represents a height direction of the display device.

Although a display device 100 according to one or more embodiments of the present disclosure is described as an organic light emitting display apparatus, the display device 100 can be implemented as a liquid crystal display (LCD) apparatus, a plasma display panel (PDP), a quantum dot light emitting display (OLED) apparatus, or an electrophoresis display apparatus and is not limited thereto.

Referring to FIGS. 1 and 2, the display device 100 according to one or more embodiments of the present disclosure can include a transparent display panel 110. The transparent display panel 110 can be divided into a display area DA and a non-display area NDA outside of the display area DA.

The non-display area NDA can be formed in an edge area surrounding the display area DA. The non-display area NDA can include GIP part 205 which is a driving part for driving the pixel and the pad part PA.

The display area DA can comprise a plurality of pixels, and images can be displayed through the pixels. Each of the plurality of pixels can include a plurality of sub-pixels. Further, each of the plurality of sub-pixels can have the configuration as shown in FIG. 2.

Referring to FIG. 2, one sub-pixel can include a switching transistor SW, a driving transistor DR, a capacitor Cst, a compensation circuit CC, and an organic light emitting diode OLED.

A first electrode (e.g., a drain electrode) of the switching transistor SW is electrically connected to a data line DL, and a second electrode (e.g., a source electrode) is electrically connected to a first node N1. A gate electrode of the switching transistor SW is electrically connected to a gate line GL. The switching transistor SW supplies a data signal supplied via the data line DL to the first node N1 in response to a scan signal supplied via the gate line GL.

The capacitor Cst is electrically connected to the first node N1 to charge the voltage applied to the first node N1.

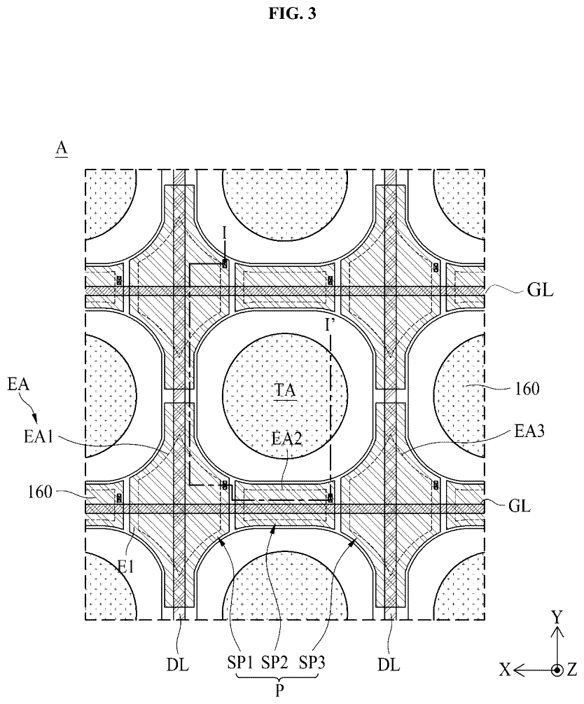

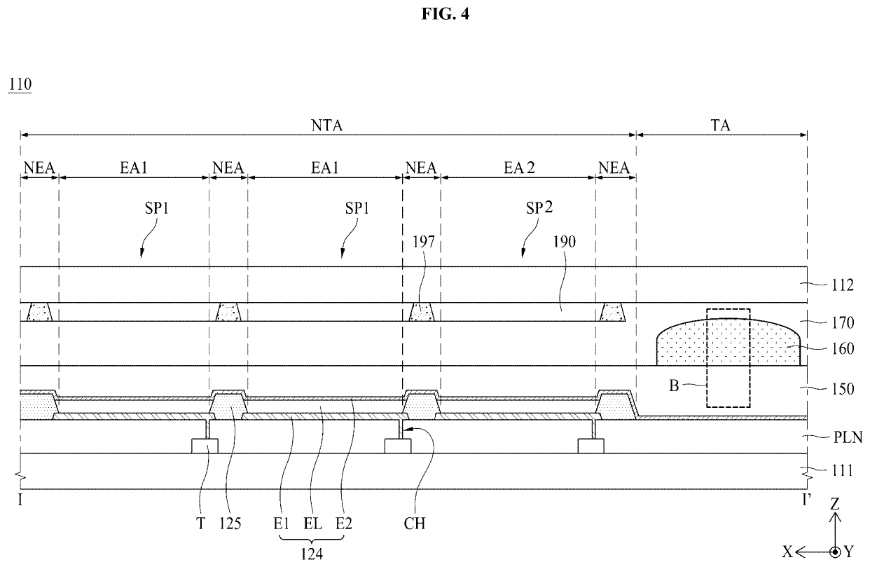

A first electrode (e.g., drain electrode) of the driving transistor DR is applied with a high potential driving voltage EVDD, and a second electrode (e.g., source electrode) is electrically connected to a first electrode (e.g., anode electrode, See E1 shown in FIGS. 3 and 4) of the organic light emitting diode OLED. The driving transistor DR can control the amount of driving current flowing to the organic light emitting diode OLED in response to a voltage applied to a gate electrode.

A semiconductor layer of the switching transistor SW and/or the driving transistor DR can include, but is not limited thereto, silicon, such as a-Si, poly-Si, or low-temperature poly-Si, or can include an oxide, such as indium-gallium-zinc-oxide IGZO.

The organic light emitting diode OLED outputs light corresponding to the driving current. The organic light emitting diode OLED can output light corresponding to any one of the red color, the green color, and the blue color.

The organic light emitting diode OLED can include an anode electrode, a light emitting layer formed on the anode electrode, and a cathode electrode which applies common voltage. The light emitting layer can be implemented to emit the same color of light per pixel, such as white light, or can be implemented to emit different colors of light per pixel, such as red light, green light, or blue light.

The compensation circuit CC can be disposed in the pixel to compensate for a threshold voltage of the driving transistor DR. The compensation circuit CC can include one or more transistors. The compensation circuit CC can include one or more transistors and capacitors and can be configured in various ways depending on the compensation method. The pixel including the compensation circuit CC can have various structures, such as 3T1C, 4T2C, 5T2C, 6T1C, 6T2C, 7T1C, 7T2C, etc.

FIG. 3 is a plan view showing pixels according to one example of region “A” of the display device shown in FIG. 1 according to an embodiment of the present disclosure. FIG. 4 is a cross-sectional view of I-I′ of FIG. 3 according to an embodiment of the present disclosure. Referring to FIGS. 3 and 4, a transparent display panel 110 according to one or more example embodiments of the present disclosure includes a first substrate 111 and a second substrate 112 facing each other, and a plurality of pixels P capable of transmitting incident light or displaying images can be arranged in the display area DA.

The display area DA of the transparent display panel 110 includes a transmissive area TA and a non-transmissive area NTA. A pixel P in the display area DA can include a plurality of sub-pixels SP1, SP2, and SP3 and a transmissive area TA.

The non-transmissive area NTA can include a plurality of emission areas EA1, EA2, and EA3, and a non-emission area NEA between the emission areas EA1, EA2, and EA3. The plurality of emission areas EA1, EA2, and EA3 of the non-transmissive area NTA can display images through areas that emit light through the light emitting device layer 124.

The emission area EA can include at least one of a plurality of emission areas EA1, EA2, and EA3 that emit different colors. For example, the plurality of emission areas EA1, EA2, and EA3 can include a red emission area, a green emission area, and a blue emission area, and can further include a white emission area. Alternatively, the plurality of emission areas EA1, EA2, EA3 can include at least two or more of the following emission areas: a red emission area, a green emission area, a blue emission area, a yellow emission area, a magenta emission area, and a cyan emission area. For instance, the red emission area is an area that emits red light, the green emission area is an area that emits green light, and the blue emission area is an area that emits blue light. The red emission area, the green emission area, and the blue emission area of the emission areas EA emit a predetermined light and correspond to a non-transmissive area NTA that does not transmit incident light.

Each of the plurality of emission areas EA1, EA2, and EA3 can have a different shape, and each of the plurality of emission areas EA1, EA2, and EA3 can have a polygonal shape.

Each of the plurality of emission areas EA1, EA2, and EA3 can have a different area size. A first electrode E1 can be disposed in each of the plurality of emission areas EA1, EA2, and EA3. The first electrode E1 disposed in each of the emission areas EA1, EA2, and EA3 can have a shape similar to the corresponding respective emission areas EA1, EA2, and EA3. The shape and size of each of the plurality emission areas EA1, EA2, and EA3 can be determined by considering the lifespan and light emitting efficiency of the light emitting device layer 124 disposed in each emission area.

For example, when a green light emitting device layer is disposed in the first emission area EA1, a red light emitting device layer is disposed in the second emission area EA2, and a blue light emitting device layer is disposed in the third emission area EA3, the blue light emitting device layer can have the shortest lifespan and the red light emitting device layer can have the longest lifespan given the same area size because shorter wavelengths of light have higher energy. Therefore, in order to achieve a uniform lifespan, the area size of the second emission area EA2 where the red emitting device layer is disposed can be set smaller than the area size of the first emission area EA1 where the green emitting device layer is disposed or the area size of the third emission area EA3 where the blue emitting device layer is disposed.

On the lines (e.g., DL) in the row direction or Y direction, the first emission area EA1 and the third emission area EA3 can be alternately arranged. On the lines (e.g. GL) in the column direction or X direction, the first emission area EA1 and the third emission area EA3 can be alternately arranged with the second emission area EA2 interposed therebetween. For example, the lines (e.g. GL) in the column direction or X direction, the first emission area EA1, the second emission area EA2 and the third emission area EA3 can be arranged from left to right.

The transmissive area TA is an area that transmits light incident from the outside, allowing viewing of an object or background located on the rear surface of the transparent display panel 110 or the first substrate 111. For example, the transmissive area TA can allow a user to view objects and scenes that are located at a rear of the transparent display device (e.g., the transmissive areas TA allow a user to see through the display device).

FIG. 3 illustrates, but is not limited thereto, the transmissive area TA elongated in the data line direction (e.g., Y-axis direction) and the emission area EA elongated in the gate line direction (e.g., X-axis direction). In other words, both the transmissive area TA and the emission area EA can be elongated in the data line direction (e.g., Y-axis direction), or both the transmissive area TA and the emission area EA can be elongated in the gate line direction (e.g., X-axis direction).

The transmissive area TA can be arranged to have a polygonal shape, but embodiments are not limited thereto. Since the transmissive area TA of the transparent display panel 110 according to the present disclosure can have a polygonal shape and opposite sides of the adjacent transmissive areas TA may not be fully parallel to each other, the parallel regularity and periodicity of the transmissive areas TA can be avoided, thereby mitigating the diffraction phenomenon of light. In order words, a repeating pattern of adjacent parallel edges from the transmissive areas TA can be softened or minimized.

Specifically, as shown in FIG. 3, the transmissive area TA of the transparent display panel 110 according to the present disclosure can have an octagonal shape including a round or curved shape, or rounded corners. When the transmissive area TA has the octagonal shape including the round or curved shape, transmissive areas TA that are adjacent to each other in a row direction or a column direction do not have opposing sides that are fully parallel to each other in at least one of the row or column, which can mitigate diffraction of light compared to transmissive areas that have opposing sides that are parallel in both the row and the column. In other words, side portions of transmissive areas TA that are adjacent to each are not fully parallel with each other. For example, harsh repeating patterns of straight edges can be avoided and a straight lined grid pattern of the transmissive areas TA can be softened.

At least one first optical pattern 160 is disposed in each of the transmissive areas TA. The first optical pattern 160 is disposed within the transmissive area TA between neighboring the non-transmissive areas NTA. The first optical pattern 160 can be disposed at the center of the transmissive area TA. The first optical pattern 160 can have a lens shape and can help focus light through the transparent display device in a direction towards a user's eyes.

As shown in FIG. 4, the above described transmissive area TA and non-transmissive area NTA are disposed on a first substrate 111 and a second substrate 112 facing each other, and transmit light incident from the outside or display images by emitting internal light.

In this situation, the at least one first optical pattern 160 can be disposed in the transmissive area TA to improve the concentrating efficiency of external light when external light from outside the display device 100 is transmitted, thereby improving the transmittance of the transmissive area TA, thereby improving transparency.

The first substrate 111 can be a plastic film, a glass substrate, or a silicon wafer substrate formed using a semiconductor process.

The second substrate 112 can be an encapsulation substrate. The second substrate 112 can be a plastic film, a glass substrate, or an encapsulation film. The first substrate 111 and second substrate 112 can be made of a transparent material.

The first substrate 111 can be formed larger than the second substrate 112. This can cause a portion of the first substrate 111 to be exposed without being covered by the second substrate 112.

A circuit element layer T is disposed on the first substrate 111 between the first and second substrates 111 and 112. Circuit elements including various signal lines, thin-film transistor, and capacitor are disposed in the circuit element layer T for each pixel. The signal lines can include gate lines, data lines, driving power lines, common power lines, and reference lines. The thin film transistor can include the switching thin film transistor, the driving thin film transistor, and the sensing thin film transistor.

A planarization film PLN is disposed on the circuit element layer T to planarize the top of the circuit element layer T.

A light emitting device layer 124 is disposed on the planarization film PLN. The light emitting device layer 124 is electrically connected to the circuit element layer T below. The light emitting device layer 124 includes a plurality of first electrodes E1, a light emitting layer EL, and a second electrode E2.

The first electrode E1 can be provided in the non-transmissive area NTA including the emission area EA and may be absent from the transmissive area TA, for enhancing a transmittance.

The first electrode E1 can include a metal material which is high in reflectivity. For example, the first electrode E1 can be a multi-layer structure such as a stacked structure (titanium/aluminum/titanium (Ti/Al/Ti)) of Al and Ti, a stacked structure (indium tin oxide/Al/indium tin oxide (ITO/Al/ITO)) of Al and ITO, an APC (silver/palladium/copper) alloy, or a stacked structure (ITO/APC/ITO) of an APC alloy and ITO, or can include a single-layer structure including one material or two or more alloy materials selected from among Ag, Al, molybdenum Mo, gold Au, magnesium Mg, calcium Ca, and barium Ba.

The light emitting layer EL can be provided on the first electrode E1. The light emitting layer EL can be an organic light emitting layer including an organic material. In this situation, the light emitting layer EL can include a hole transporting layer, an organic light emitting layer, and an electron transporting layer.

The light emitting layer EL can be provided in the non-transmissive area NTA including the emission area EA and can be absent from the transmissive area TA, for enhancing a transmittance.

When voltages are applied to the first electrode E1 and the second electrode E2, holes and electrons are transported to the organic light emitting layer through the hole transporting layer and the electron transporting layer, respectively, and they can be combined with each other in the organic light emitting layer to emit light.

The light emitting layer EL can include a red light emitting layer emitting red light, a green light emitting layer emitting green light, and a blue light emitting layer emitting blue light. The red light emitting layer, the green light emitting layer, and the blue light emitting layer can be patterned on the first electrode E1 by sub-pixels SP1, SP2, and SP3. The red light emitting layer can be patterned in a red pixel, the green light emitting layer can be patterned in a green pixel, and the blue light emitting layer can be patterned in a blue pixel. However, the present disclosure is not limited thereto. Alternatively, the light emitting layer EL can be a white light emitting layer emitting white light. In this situation, the light emitting layer EL can be a common layer which is formed in the sub-pixels SP1, SP2, and SP3 in common.

The light emitting layer EL can be provided in a tandem structure of two or more stacks. Each of the stacks can include the hole transporting layer, at least one organic light emitting layer, and the electron transporting layer. A charge generating layer can be provided between the stacks.

The second electrode E2 can be provided over the light emitting layer EL. The second electrode E2 can be provided in the transmissive area TA as well as in the non-transmissive area NTA including the emission area EA, but is not limited thereto.

The second electrode E2 can be provided in only the non-transmissive area NTA including the emission area EA and can be absent in the transmissive area TA, for enhancing a transmittance. The second electrode E2 can be a common layer provided in the pixels P and the same voltage is applied.

The second electrode E2 can include a transparent conductive material TCO, such as indium tin oxide ITO or indium zinc oxide IZO, or a semi-transmissive conductive material such as magnesium Mg, silver Ag, or an alloy of Mg and Ag, which transmit light. When the second electrode E2 is formed of the semi-transmissive conductive material, emission efficiency can be increased by a micro-cavity.

The light emitting device layer 124 can be a pixel array layer in which the pixels P are formed, and the area in which the light emitting device layer 124 is formed can be defined as a display area DA. Sub-pixels SP1, SP2, and SP3 within the display area DA can be partitioned or defined by a bank 125.

The bank 125 can be provided at an end of the first electrode E1. Therefore, adjacent first electrodes E1 can be electrically insulated from each other, and emission efficiency can be prevented from being reduced by the concentration of a current on the end of the first electrode E1.

The bank 125 can form an opening portion to expose the planarization film PLN in the transmissive area TA. The bank 125 can be absent in the transmissive area TA, thereby enhancing a transmittance of the transmissive area TA. The bank 125 can extend from an end of one first electrode E1 to an end of another first electrode E1 disposed adjacent thereto. For example, the bank 125 can cover the edges of first electrodes in adjacent subpixels.

The encapsulation layer 150 can be provided over the light emitting device layer 124. The encapsulation layer 126 can prevent penetration of oxygen or water into the light emitting device layer 124. The encapsulation layer 150 can include at least one inorganic film and at least one organic film. The encapsulation layer 150 can be formed in a structure where the inorganic film and the organic film are alternately stacked, but is not limited thereto.

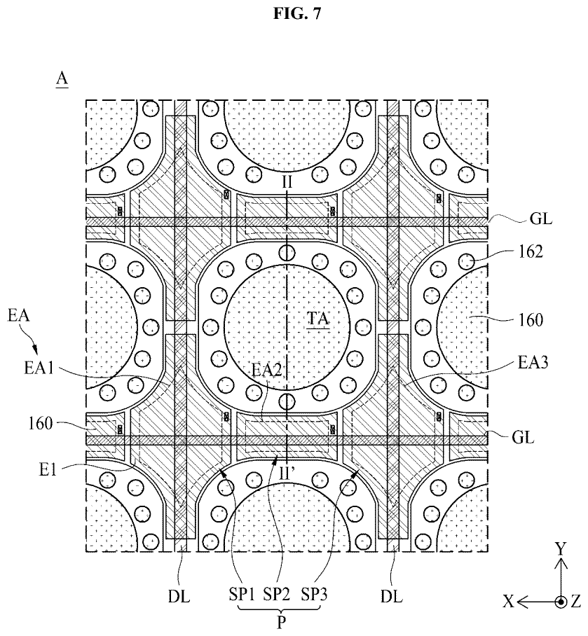

Specifically, as shown in FIG. 6, the encapsulation layer 150 can be formed in a structure where a first inorganic film 151, a second inorganic film 153, a third inorganic film 154, a fourth inorganic film 155, a first organic film 157, and a fifth inorganic film 159 are stacked.

At least one first optical pattern 160 is disposed on the encapsulation layer 150 in the transmissive area TA. The first optical pattern 160 is disposed within the transmissive area TA to increase the concentrating efficiency of the external light when the external light outside the first substrate passes through the transmissive area TA (e.g., 160 can be a type of lens for focusing light towards a user's eyes from objects that are located behind the transparent display device).

Specifically, when light outside or behind the transparent display panel 110 passes through the first substrate 111, the planarization layer PLN, and the encapsulation layer 150 of the transparent area TA, the transmittance can be reduced. However, when the light outside or behind the transparent display panel 110 passes through the at least one first optical pattern 160 disposed on the encapsulation layer 150, the first optical pattern 160 can cause the external light to be refracted, multiple reflected or diffusely reflected, and thus concentrated or focused, thereby improving the concentrating efficiency of the external light. In this way, a user can have a better view when viewing objects through the transparent display panel 110 and improved clarity can be provided.

Accordingly, the display device 100 according to the present disclosure can improve transparency by improving the concentrating efficiency of external light by the at least one first optical pattern 160 disposed in the transmissive area TA. Also, the display device 100 according to the present disclosure can improve the brightness of the display device 100 by increasing the size of the emission area EA relative to the size of the transmissive area TA, and reduce power consumption without compromising the brightness. For example, since the transmissive areas TA can better focus light towards a viewer's eyes, the transmissive areas TA can be made smaller without unduly impairing the transparency of the transparent display panel and the emission areas EA can be made larger to improve brightness and provide better quality and color for displayed images.

Thus, the display device 100 according to the present disclosure can implement low power and extend the lifespan of the display device, and as the lifespan of the display device increases, the manufacturing process for producing a new display device can be reduced. Thus, the generation of greenhouse gases due to the manufacturing process can be reduced, thereby enabling ESG (Environment/Social/Governance).

The first optical pattern 160 on the encapsulation layer 150 disposed in the transmissive area TA can have a convex shape or a curved portion from the upper surface of the encapsulation layer 150 on the first substrate 111 with respect to the first substrate 111 (e.g., a dome shape or a lens shape). In other words, the first optical pattern 160 can curve outward/upward from the upper surface of the encapsulation layer 160 such that the first optical pattern 160 is thicker in the middle then the edges.

The first optical pattern 160 can have convex shape including a cylinder shape, or the first optical pattern 160 can have a semi-cylindrical base having a predetermined height and a hemispherical lens shape on the semi-cylindrical base.

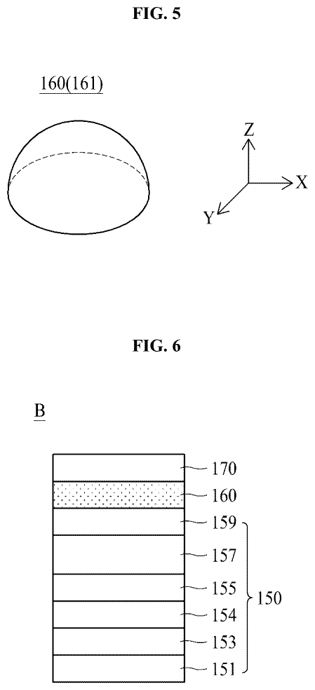

As shown in FIG. 5, the first optical pattern 160 can have a hemispherical lens shape 161. The first optical pattern 160 having a hemispherical lens shape 161 can have a semicircular cross-section in the X and Y directions.

As shown in FIG. 3, the first optical pattern 160 is disposed within the transmissive area TA and the border or edge of the first optical pattern 160 is disposed adjacent to a border between the transmissive area TA and the non-transmissive area NTA. The first optical pattern 160 can be disposed such that it is spaced apart from the edge of the transmissive area TA. For example, a center of the first optical pattern 160 can overlap with a center of the transmissive area TA.

The first optical pattern 160 can be a pattern including a hemispherical transparent insulating material. The first optical pattern 160 can be made of an organic insulating material. The first optical pattern 160 can be made of an organic insulating material such as photo acrylic or glass.

An optical insulating layer 170 can cover the first optical pattern 160, disposed in the non-transmissive area NTA and transmissive area TA, and disposed on the encapsulation layer 150.

The optical insulating layer 170 is disposed between the first optical pattern 160 and the second substrate 112 to mitigate a step difference caused by the first optical pattern 160. The optical insulating layer 170 can have a flat top surface and cover the first optical pattern 160 with the convex top surface. The optical insulating layer 170 does not have a curve surface similar to the curved portion of the first optical pattern 160 and can have a flat top surface.

When the upper surface of optical insulating layer 170 is curved due to the first optical pattern 160, a haze phenomenon may increase as well as undesirable reflections. The optical insulating layer 170 can planarize the upper surface of the first optical pattern 160 to prevent the haze phenomenon from increasing and reduce undesirable reflections.

The optical insulating layer 170 disposed on the first optical pattern 160 can bond or seal the second substrate 112 to the first substrate 111 on which the circuit element layer T, the planarization film PLN, the light emitting device layer 124, and the encapsulation layer 150 are formed.

The optical insulating layer 170 can comprise an organic insulating material. The optical insulating layer 170 can be made of photo acryl, benzocyclobutene BCB, polyimide PI, or polyamide PA.

The optical insulating layer 170 can be an optically clear resin layer OCR or an optically clear adhesive film OCA.

The color filter 190 can further be disposed between the optical insulating layer 170 of the non-transmissive area NTA and the second substrate 112. The color filter 190 can be disposed on one surface of the second substrate 112 facing the first substrate 111. The color filter 190 can be disposed to each of the emission areas EA1, EA2, and EA3 per sub-pixels SP1, SP2, and SP3. For example, the color filter 190 can include a red color filter disposed to an emission area EA of the red sub-pixel, a green color filter disposed to an emission area EA of the green sub-pixel, and a blue color filter disposed to an emission area EA of the blue sub-pixel.

The color filter 190 provided in each of sub-pixels SP1, SP2, and SP3 can be formed to cover the emission area EA. That is, the color filter 190 can have the same area size as that of a minimum size of emission area EA or can have an area size which is larger than that of the emission area EA. Also, the color filter 190 can have the same area width as that of a minimum width of emission area EA or can have an area width which is wider than that of the emission area EA.

The second substrate 112 which is upper substrate can be bonded on the color filter 190. Additionally, without a bonding process to avoid damaging the organic film layer which is vulnerable to high temperatures, the upper part can be finished in a COE (color-filter on encap) method where a low-temperature color filter process is applied to the substrate.

An insulating layer may further be disposed between the second substrate 112 and the color filter 190. The insulating layer may serve as an adhesive layer, and the insulating layer may comprise an organic or inorganic material. In the transparent display panel 110 according to one or more embodiments of the present disclosure, the color filter 190 can be formed on the second substrate 112 and light incident from the outside can be prevented from being reflected by the electrodes E1 and E2 inside the transparent display device 110. That is, the transparent display panel 110 according to one or more embodiments of the present disclosure can decrease an external light reflectance without reducing a transmittance.

A black matrix 197 can be provided between the color filters 190, e.g., at the edges of the transmissive areas TA. The black matrix 197 can be disposed in a pattern in the non-emission area NEA per sub-pixels SP1, SP2, and SP3. The black matrix 197 can be arranged to correspond to the bank 125. For example, the black matrix 197 disposed between the first emission area EA1 and another first emission area EA1 can be directly above the bank 125 located between the first emission area EA1 and the another first emission area EA1.

The black matrix 197 can be disposed to correspond to the non-emission area NEA to prevent light incident from the outside from being reflected by the plurality of lines inside the transparent display panel 110. A black matrix 197 may be absent from the transmissive area TA.

The black matrix 197 can be disposed between each of the sub-pixels SP1, SP2, and SP3 in the non-transmissive area NTA. For example, the black matrix 197 can be disposed between the sub-pixel SP1 and the sub-pixel SP2, and another black matrix 197 can be disposed between the sub-pixel SP2 and the sub-pixel SP3. Also, another black matrix 197 can be disposed between the sub-pixel SP3 and the transmissive area TA. The black matrix 197 can be disposed between the sub-pixels SP1, SP2, and SP3 to prevent color mixing between adjacent sub-pixels SP1, SP2, and SP3.

The black matrix 197 can include a light-absorbing material, such as a black dye for absorbing all light within a visible light wavelength band. Further, the black matrix 197 can comprise a stacked structure of neighboring color filters 190 of adjacent sub-pixels. For example, the black matrix 197 can be composed of a stacked structure of the red color filter, the green color filter, and the blue color filter disposed correspondingly to each of the sub-pixels SP1, SP2, and SP3.

The black matrix 197, which comprises a stacked structure of the red color filter, the green color filter, and the blue color filter overlapping with each other, can be disposed between the pixels P, which are defined by a collection of at least three sub-pixels SP1, SP2 and SP3.

Since the black matrix 197, which comprises the stacked structure of the red color filter, the green color filter, and the blue color filter, can be disposed together when the color filters are formed, the production process time, production energy, and the manufacturing process can be reduced, thereby reducing the generation of greenhouse gases due to the manufacturing process, and thereby implementing ESG.

Although the transparent display panel 110 is illustrated as implemented in a top emission method, it is not limited thereto and can also be implemented in a bottom emission method. In the top emission method, light emitted from the light emitting layer EL is directed toward the second substrate 112, so that the circuit element layer T can be spaced far below the bank 125 and the first electrode E1. Therefore, the top emission method has the advantage of a larger design area for the circuit element layer T compared to the bottom emission method.

As described above, each of the pixels P of the display device 100 including the transparent display panel 110 according to one or more embodiments of the present disclosure includes at least one the first optical pattern 160 disposed in the transmissive area TA that passes external light through the transparent display panel and the emission area EA that displays images. As a result, the transparent display panel 110 according to one or more embodiments of the present disclosure or the display device 100 equipped with the transparent display panel 110 can improve the transmittance of the transmissive areas TA through which an object or background located on the rear surface can be seen, while at the same time improving the brightness of the light emitted from the emission area EA.

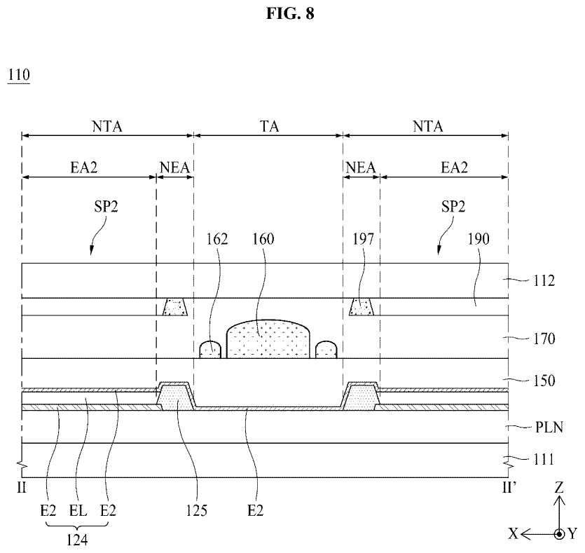

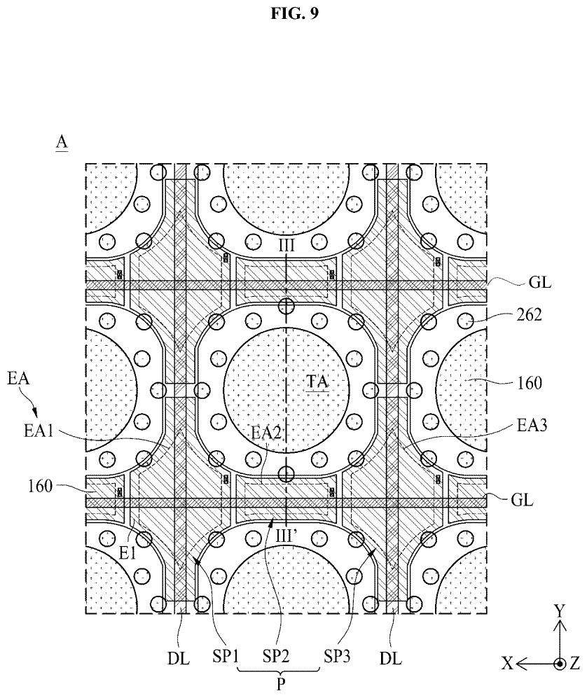

FIG. 7 illustrates a plurality of pixels P according to another embodiment in an area A in a display apparatus 100 according to another embodiment of the present description, and FIG. 8 is a cross-sectional view of II-II′ of FIG. 7 according to an embodiment of the present disclosure. Hereinafter, the description omits the redundant description of the like reference numerals described above.

As shown in FIGS. 7 and 8, the display device 100 according to another embodiment of the present disclosure includes a transparent display panel 110 having a transmissive area TA and a non-transmissive area NTA in the display area DA, formed by bonding a first substrate 111 and a second substrate 112.

The transparent display panel 110 can transmit external light through it with a transmissive area TA and display images with internally generated light emitted through a non-transmissive area NTA of the display area DA disposed on the first substrate 111 and the second substrate 112 facing each other.

The non-transmissive area NTA includes a plurality of emission areas EA1, EA2, and EA3 defined by the bank. The first optical pattern 160 is disposed on each of the transmissive areas TA. A plurality of second optical patterns 162 can be disposed between the first optical pattern 160 and an edge of transmissive area TA. For example, the first optical pattern 160 can be positioned between a second optical pattern 162 adjacent to a non-transmissive area NTA and another second optical pattern 162 adjacent to another non-transmissive area NTA. In other words, the first optical pattern 160 can be disposed in a center of the transmissive area TA and the second optical patterns 162 can be disposed around the first optical pattern 160 in the transmissive area TA.

The plurality of emission areas EA1, EA2, and EA3 can display the images and light is emitted through the plurality of emission areas EA1, EA2, and EA3 using the light emitting device layer 124.

The emission area EA can comprise at least one of a plurality of emission areas EA1, EA2, and EA3 that emit different colors. For example, the plurality of emission areas can include a red emission area, a green emission area, and a blue emission area, and can further include a white emission area. Alternatively, the plurality of emission areas EA1, EA2, and EA3 can include at least two of the among a red emission area, a green emission area, a blue emission area, a yellow emission area, a magenta emission area, and a cyan emission area. A red emission area is an area that emits red light, a green emission area is an area that emits green light, and a blue emission area is an area that emits blue light. The red emission area, the green emission area, and the blue emission area of the emission areas EA emit a predetermined light and correspond to the non-transmissive area NTA that does not transmit incident light.

Each of the plurality of emission areas EA1, EA2, and EA3 can have a different shape. For example, each of the plurality of emission areas EA1, EA2, and EA3 can have different polygonal shapes, different curved shapes or different polygonal and curved shapes. For example, the plurality of emission areas EA1, EA2, and EA3 can have different shapes to fill in the areas between the transmissive areas TA.

Each of the emission areas EA1, EA2, and EA3 can have a different area. The shape and size of each of the emission areas EA1, EA2, and EA3 can be determined by considering the lifespan and light emitting efficiency of the light emitting device layer 124 disposed in each of the emission areas EA1, EA2, and EA3.

For example, when a green light emitting device layer is disposed in the first emission area EA1, a red light emitting device layer is disposed in the second emission area EA2, and a blue light emitting device layer is disposed in the third emission area EA3, the blue light emitting device layer can have the shortest lifespan and the red light emitting device layer can have the longest lifespan in the same area because shorter wavelengths of light have higher energy. Therefore, in order to achieve a uniform lifespan, the area size of the second emission area EA2 where the red emitting device layer is disposed can be smaller than the area size of the first emission area EA1 where the green emitting device layer is disposed or the area size of the third emission area EA3 where the blue emitting device layer is disposed.

On the lines in the column direction or Y direction (e.g., DL), the first light emission area EA1 and the third emission area EA3 may be arranged alternately. On the lines in the row direction or X direction (e.g. GL), the first emission area EA1 and the third emission area EA3 can be arranged alternately with the second emission area EA2 in therebetween.

In detail, on the line (e.g. GL) in a predetermined row direction or X direction, a green light emitting device layer can be disposed in the first emission area EA1, a red light emitting device layer can be disposed in the second emission area EA2, and a blue light emitting device layer can be disposed in the third emission area EA3. On the subsequent line in the row direction or X direction (e.g., GL), a blue light emitting device layer can be disposed in the first emission area EA1, a red light emitting device layer can be disposed in the second emission area EA2, and a green light emitting device layer can be disposed in the third light emitting region EA3.

The transmissive area TA is an area that transmits light incident from the outside (e.g., from behind the transparent display device), allowing viewing of an object or background located on the rear surface of the transparent display panel 110 or the first substrate 111 to be visible to a user.

The transmission area TA can be disposed to have a polygonal shape or a curved shape. The transmissive area TA can also be disposed to have a polygonal shape including curves and rounded corners. The transmissive area TA of the transparent display panel 110, according to another embodiment of the present disclosure, includes a first optical pattern 160 within the transmissive area TA and a plurality of second optical patterns 162 between the first optical pattern 160 and the non-transmissive area NTA, as shown in FIGS. 7 and 8.

At least one first optical pattern 160 is disposed in each of the transmissive areas TA to increase the concentrating efficiency of externally light. A center point of the first optical pattern 160 can be disposed to correspond to a center point of the transmissive area TA. In one example, the first optical pattern 160 disposed within the transmissive area TA can be disposed in the center of the transmissive area TA.

The first optical pattern 160 can have a convex shape or a curved portion from the top surface of the encapsulation layer 150 on the first substrate 111 with respect to the first substrate 111. The first optical pattern 160 can be convex shape including a cylindrical shape, or the first optical pattern 160 can have a semi-cylindrical base having a predetermined height and a hemispherical lens shape on the semi-cylindrical base.

As shown in FIG. 5, the first optical pattern 160 can have a hemispherical lens shape 161, the first optical pattern 160 having a hemispherical lens shape 161 can have a semicircular cross-section in the X and Y directions.

The transmissive area TA can comprise an embossing pattern or a concavo-convex pattern. The embossing pattern or concavo-convex pattern is formed on a border area of the transmissive area TA. The border area includes not only a border line between the transmissive area TA and the non-transmissive area NTA but also an area within a predetermined range from the border line.

The embossing pattern or concavo-convex pattern can be formed by an edge or shape of a plurality of second optical patterns 162 disposed in the border area of the transmissive area TA. The border area is an area between the first optical pattern 160 and the non-transmissive area NTA. The embossing pattern or concavo-convex pattern can be a pattern corresponding to the edge or shape of the plurality of second optical patterns 162 disposed on the border area of the transmissive area TA.

The embossing pattern or concavo-convex pattern can be described as having a plurality of patterns in which an edge area or the border area of the transmissive area TA that protrudes toward the non-transmissive area NTA when viewed in plan view. Here, the edge area or the border area of the transmissive area TA protruding toward the non-transmissive area NTA can include an embossing pattern or a concavo-convex pattern having a round or curved shape.

For example, the edge area or the border area the transmissive area TA can be at least a portion of the transmissive area TA or an edge or end of the transmissive area TA including at least a portion of the transmissive area TA.

As shown in FIG. 8, the plurality of second optical patterns 162 can be disposed on the encapsulation layer 150 of the transmissive area TA and can be disposed at the border area of the transmissive area TA. The second optical pattern 162 can be spaced apart from the edge of the first optical pattern 160 and can be disposed at the border area of the transmissive area TA.

Since the plurality of second optical patterns 162 are disposed between the first optical pattern 160 and the non-transmissive area NTA, the diffraction phenomenon can be further reduced and the haze phenomenon can be improved. The embossing shape or concavo-convex shape of the plurality of second optical patterns can further prevent or soften periodic repetition and regularity of the lines in the border area of the transmissive areas TA, thereby reducing the diffraction issue and improving visual transparency for a viewer.

Specifically, by arranging the plurality of second optical patterns 162 at the border area of the transmissive area TA, the border area of the transmissive area TA can have an embossing shape or a concavo-convex shape as shown in FIG. 7 when viewed in plan view. Generally, the transmissive area TA serves as a slit, and diffraction phenomenon in which the direction of light is curved may occur in the slit, which can be undesirable. The diffraction phenomenon causes haze, and the border area of the transmissive area TA of the display device 100 according to the present disclosure can have the embossing shape or concavo-convex shape to avoid periodic repetition and regularity of the lines on the border area of the transmissive area TA. Furthermore, the display device 100 according to the present disclosure can reduce the parallel arrangement between the border areas of the transmissive areas TA that are adjacent to each other, thereby reducing the occurrence of diffraction phenomenon and reducing haze. Thus, the display device 100 with the transparent display panel 110 according to the present disclosure can improve the image quality, clarity, and visibility of the display device and can improve readability.

The transmittance of the second optical pattern 162 disposed at the border area of the transmissive area TA can be different from the transmittance of the first optical pattern 160 disposed within the transmissive area TA. A height of the second optical pattern 162 can be lower than a height of the first optical pattern 160. A size of the second optical pattern 162 can be smaller than a size of the first optical pattern 160. A width of the second optical pattern 162 can be smaller than a width of the first optical pattern 160.

By controlling the transmittance of the second optical pattern 162 disposed at the border area of the transmissive area TA to be different than the transmittance of the first optical pattern 160 disposed within the transmissive area TA, the periodicity, repeatability, parallelism, etc. of the border area of the transmissive area TA can be avoided, e.g., the transition can be further softened or made more gradual, thereby reducing the occurrence of diffraction phenomenon and improving haze. Therefore, the display device 100 with the transparent display panel 110 according to the present disclosure can prevent the border area between the emission area EA and the transmissive area TA from being visually noticeable to a user, thereby improving readability and enhancing visibility.

The second optical pattern 162 can be disposed to have a different shape than the first optical pattern 160. The second optical pattern 162 can have a convex shape or a curved shape from the top surface of the encapsulation layer 150 on the first substrate 111. The second optical pattern 162 can be the convex shape including a cylindrical shape, or the second optical pattern 162 can be a pattern having a semi-cylindrical base having a predetermined height and a hemispherical lens shape on the semi-cylindrical base. For example, the second optical pattern 162 can have a rounded peg type of shape.

The second optical pattern 162 can be smaller in size than the first optical pattern 160, but can have the same shape as the first optical pattern 160. The second optical pattern 162 can have a hemispherical lens shape 161 as shown in FIG. 5. The second optical pattern 162 having a hemispherical lens shape 161 can have a semicircular cross-section in the x-direction and y-direction.

The horizontal width of the second optical pattern 162 can be smaller than the horizontal width of the first optical pattern 160. Alternatively, when the second optical pattern 162 has a hemispherical lens shape, the diameter of the second optical pattern 162 can be smaller than the diameter of the first optical pattern 160.

The second optical pattern 162 can be disposed in the same layer and made of the same material as the first optical pattern 160.

The second optical pattern 162 can be a hemispherical pattern or elliptical pattern including a transparent insulating material. The second optical pattern 162 can be made of an organic insulating material. The second optical pattern 162 can include an organic insulating material of the photoacrylic type.

The height of the second optical pattern 162 disposed at the border area of the transmissive area TA can be lower than the height of the first optical pattern 160 disposed within the transmissive area TA. When the height of the second optical pattern 162 is lower than the height of the first optical pattern 160, the occurrence of a sharp step between the emission area EA and the transmissive area TA can be mitigated or prevented.

Specifically, the second optical pattern 162 disposed at the border area of the transmissive area TA is disposed between the emission area EA and the transmissive area TA, so that when the second optical pattern 162 has a thinner thickness or a lower height than the first optical pattern 160, the deviation of the step at the border area of the emission area EA adjacent to the border area of the transmissive area TA can be reduced. As the deviation of the step at the border area of the emission area EA is reduced, the display device 100 according to the present disclosure can prevent or reduce light distortion or image distortion due to the step when light generated in the emission area EA passes through the plurality of layers toward the second substrate 112.

Accordingly, the display device 100 according to the present disclosure can further improve the image quality of the display device 100 by controlling the height, width, or size of the second optical pattern 162 disposed at the border area of the transmissive area TA to be smaller than the height, width, or size of the first optical pattern 160.

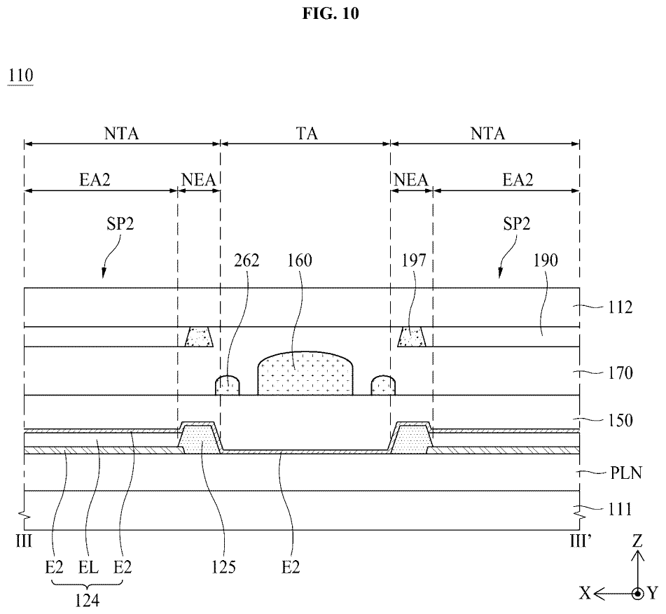

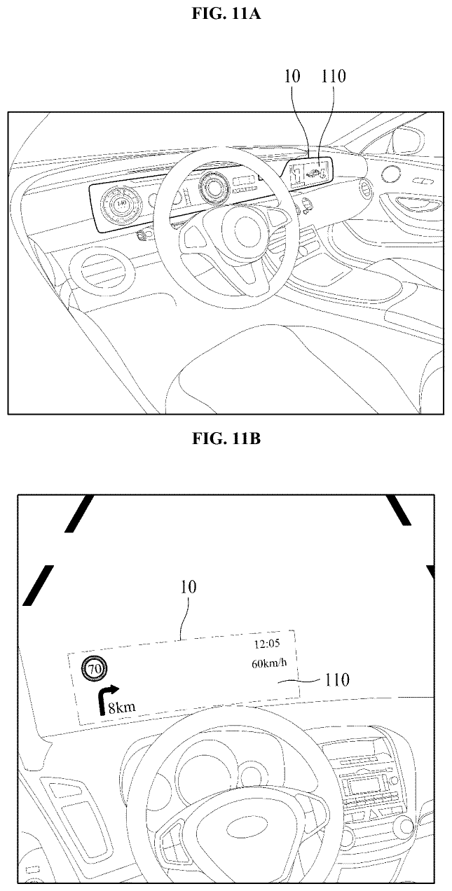

As shown in FIGS. 9 and 10, in accordance with another embodiment of the present disclosure, the second optical pattern 262 at the border area of the transmissive area TA can be irregularly spaced apart from the edge of the first optical pattern 160 at the border area of the transmissive area TA.

At least some of the plurality of second optical patterns 262 can overlap with a border line of the transmissive area TA or overlap with a border line of the non-transmissive area NTA.

The transmissive area TA can comprise an embossing pattern or a concavo-convex pattern. The embossing pattern or concavo-convex pattern can be formed by an edge or shape of a plurality of second optical patterns 262 irregularly disposed at border area of the transmissive area TA. The embossing pattern or concavo-convex pattern can be a pattern corresponding to an edge or shape of the plurality of second optical patterns 262 disposed at the border area of the transmissive area TA.

The embossing pattern or concavo-convex pattern can be described as having a plurality of patterns in which the border area of the transmissive area TA protrudes or approaches toward the non-transmissive area NTA or in which the border area of the non-transmissive area NTA protrudes toward the transmissive area TA when viewed in plan view. Here, the border area of the transmissive area TA protruding or approaching toward the non-transmissive area NTA or the border area of the non-transmissive area NTA protruding toward the transmissive area TA can include the embossing pattern or the concavo-convex pattern having a round or curved shape.

When the plurality of second optical patterns 262 are disposed at the border area of the transmission area TA, the second optical patterns 262 can be disposed in a zigzag arrangement, a random arrangement, or an irregular arrangement.

For example, a predetermined second optical pattern 262 disposed at the border area of the transmissive area TA can be spaced apart from the edge of the first optical pattern 260 more or less than a subsequent second optical pattern 162 disposed at the border area of the transmissive area TA.

Alternatively, a predetermined second optical pattern 262 disposed at the border area of the transmissive area TA can be disposed to overlap with the border area of the transmissive area TA or the border area of the non-transmissive area NTA more or less than a subsequent second optical pattern 162 disposed at the border area of the transmissive area TA.

Alternatively, a predetermined second optical pattern 262 disposed at the border area of the transmissive area TA can be disposed to at least partially overlap with a border of the non-transmissive area NTA, and a subsequent second optical pattern 262 disposed at the border area of the transmissive area TA can be disposed to not overlap with the border of the non-transmissive area NTA.

The plurality of second optical patterns 262 can be disposed to at least partially overlap both of the non-transmissive area NTA and the transmissive area TA.

A second optical pattern 262 disposed at a corner of the transmissive area TA among the plurality second optical patterns 262 can be disposed to at least partially overlap with the border of the non-transmissive area NTA. At least one second optical pattern 262 can be disposed at the border area of the transmissive area TA to overlap with the non-transmissive area NTA adjacent to a corner of the emission area TA or the corner of the transmissive area TA.

A second optical pattern 262 disposed on the linear border area of the transmissive area TA among the plurality of second optical patterns 262 can be disposed to at least partially overlap with the border of the non-transmissive area NTA.

When the second optical patterns 262 are disposed at the border area of the transmissive area TA so that separation distances from the edge of the first optical pattern 160 disposed at the center of the transmissive area TA are different from each other, the transmissive areas TA disposed adjacent to each other may not have opposite sides disposed parallel to each other, and the periodicity, repeatability, parallelism, etc. of the border line of the transmissive area TA can be softened or avoided, thereby further reducing the occurrence of diffraction phenomenon and further improving haze.

The haze phenomenon may be made worse by long, hard edges or straightness. In the transparent display panel 110 according to another embodiment of the present disclosure, by disposing the at least one second optical pattern 262, at the border where edges or straightness of the transmissive area TA may exist, to overlap with the border between the non-transmissive area NTA and the transmissive area TA this configuration can further reduce the occurrence of diffraction phenomena and further improve the haze to prevent the image or view from becoming blurry.

On the other hand, when the upper part is curved due to the shape of the first optical pattern 160 and/or the second optical patterns 162 and 262, the haze phenomenon may increase (e.g., the upper surface may become dimpled or wavy). To prevent this, the optical insulating layer 170 can be disposed on the first optical pattern 160 and/or the second optical patterns 162 and 262. The optical insulation layer 170 can cover the first optical pattern 160 and/or the second optical patterns 162 and 262 to planarize the upper surface of the first optical pattern 160 and/or the second optical patterns 162 and 262 and provide a continuous, flat upper surface, in order to prevent the haze phenomenon.

Thus, the display device 100 with the transparent display panel 110 according to another embodiment of the present disclosure can prevent the borders of the emission area EA and the transmissive area TA from being visible to the user, thereby improving readability and enhancing visibility.

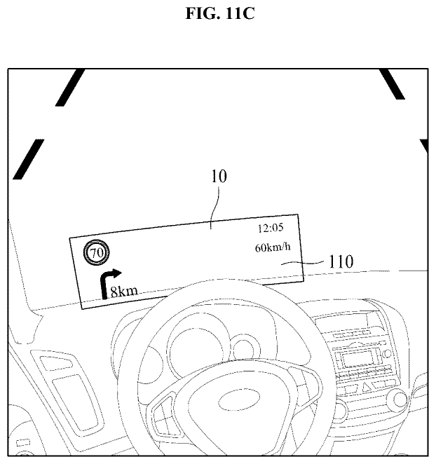

The display device 100 including the transparent display panel 110 as described above can further include a tempered glass 10 disposed on the transparent display panel 110 to enhance mobility, for cases when the display device 100 is equipped in a vehicle. For example, as illustrated in FIGS. 11A to 11C, transparent display panel 110 can be disposed on the center fascia or dashboard of the vehicle with the tempered glass 10, or can be disposed integrally with the windscreen or windshield behind the steering wheel of the vehicle, or can be disposed in a form such a heads-up display HUD disposed between the steering wheel and the windscreen of the vehicle, to allow the driver to view necessary information for driving the vehicle or to view general information while keeping the driver's head up. A mobility type display device with the transparent display panel 110 according to the present disclosure can display an image corresponding to a speedometer, a tachometer, a fuel gauge, an odometer, a coolant thermometer, a turn signal indicator, a low fuel warning light, an alternator warning light, a signal lamp, a clock, or the like. In addition, the mobility type display device with the transparent display panel 110 according to the present disclosure can also display a navigation screen for displaying a map or road to a destination of the map. Also, transparent display panel 110 can be disposed in the visor of a helmet (e.g., motorcycle helmet, etc.), on windows or glass walls to display advertisements or broadcast news without blocking the outside view or natural light.

In the present disclosure, since at least one optical pattern is disposed in the transmissive area, concentrating efficiency of external light can be improved when external light passed through the display device, thereby improving transparency.

Moreover, in the present disclosure, the plurality of optical patterns can be disposed at the border area of the transmissive area. Accordingly, in the present disclosure, a regularity and a periodicity at the border area of the transmissive area can be avoided to minimize the occurrence of diffraction phenomenon of light, thereby reducing haze values, thus improving the image quality clarity or visibility of the display device and improving readability.

Moreover, in the present disclosure, by disposing at least one optical pattern that overlaps a border between the transmissive area and the non-transmissive area adjacent a corner of the emission area or a corner of the transmissive area, diffraction can be minimized to prevent the image blurring or prevent a hazy viewing experience.

Moreover, in the present disclosure, by controlling the height or size of the optical pattern disposed at the border area of the transmissive area to be smaller than the height or size of the optical pattern disposed within the transmissive area, distortion of the image through the emission area can be prevented, thereby improving image quality clarity.

Moreover, in the present disclosure, by implementing a black matrix using color filters of adjacent sub-pixels, the manufacturing process for producing the display devices can be reduced and the generation of greenhouse gases due to the manufacturing process can be reduced, thereby implementing ESG (Environment/Social/Governance).

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A transparent display device, comprising:
a display area including a transmissive area and a non-transmissive area;
a plurality of emission areas disposed in the non-transmissive area, the plurality of emission areas being configured to emit light; and
at least one first optical pattern disposed in the transmissive area.

2. The transparent display device of claim 1, wherein the first optical pattern corresponds to a center of the transmissive area.

3. The transparent display device of claim 1, further comprising a plurality of second optical patterns disposed in a border area of the transmissive area, the border area including a border line between the transmissive area and the non-transmissive area and an area within a predetermined range from the border line.

4. The transparent display device of claim 3, wherein the plurality of the second optical patterns are spaced apart from each other and spaced apart from the first optical pattern.

5. The transparent display device of claim 3, wherein a distance between at least one of the plurality of second optical patterns and the first optical pattern is different than a distance between at least another one of the plurality of second optical patterns and the first optical pattern.

6. The transparent display device of claim 3, wherein at least one of the plurality of second optical patterns at least partially overlaps with a border of the non-transmissive area.

7. The transparent display device of claim 3, wherein at least one of the plurality of second optical patterns at least partially overlaps with a border of the non-transmissive area in a region adjacent to a corner of the transmissive area.

8. The transparent display device of claim 3, wherein a height of the plurality of second optical patterns is lower than a height of the first optical pattern.

9. The transparent display device of claim 3, wherein a width of the plurality of second optical patterns is narrower than a width of the first optical pattern.

10. The transparent display device of claim 3, wherein each of the plurality of second optical patterns have a hemispherical lens shape or an elliptical lens shape.

11. The transparent display device of claim 3, wherein the plurality of second optical patterns are disposed on a same layer as the first optical pattern and made of a same material as the first optical pattern.

12. The transparent display device of claim 3, further comprising:
a light emitting device layer disposed in the plurality of emission areas, the light emitting device layer including a first electrode, a light emitting layer, and a second electrode; and
an encapsulation layer disposed on the light emitting device layer,
wherein the first optical pattern and the plurality of the second optical pattern are disposed on the encapsulation layer.

13. The transparent display device of claim 12, further comprising an optical insulating layer overlapping with the first optical pattern and the plurality of second optical patterns on the encapsulation layer.

14. The transparent display device of claim 1, wherein the transmissive area has a polygonal shape including curved shape or rounded corners.

15. The transparent display device of claim 1, wherein the first optical pattern has a hemispherical lens shape.

16. The transparent display device of claim 1, wherein the first optical pattern has a semi-cylindrical base having a predetermined height and a hemispherical lens shape on the semi-cylindrical base.

17. The transparent display device of claim 1, wherein a border area of the transmissive area has an embossing pattern or a concavo-convex pattern.

18. The transparent display device of claim 17, wherein at least a portion of the embossing pattern or the concavo-convex pattern overlaps with a border of the non-transmissive area.

19. A display device, comprising:
a transparent display panel including a transmissive area and a non-transmissive area in a display area of a substrate; and
a tempered glass disposed on the transparent display panel,
wherein a first optical pattern is disposed in a center of the transmissive area, and
wherein a plurality of second optical pattern are spaced apart from the first optical pattern and disposed at a border area of the transmissive area, the border area including a border line between the transmissive area and the non-transmissive area and an area within a predetermined range from the border line.

20. The display device of claim 19, wherein a height of each of the plurality of second optical patterns is lower than a height of the first optical pattern, or a width of each of the plurality of second optical patterns is less than a width of the first optical pattern, or a size of each of the plurality of second optical patterns is smaller than a size of the first optical pattern.

21. A transparent display panel, comprising:
a display area including a transmissive area and a non-transmissive area;
a plurality of subpixels disposed in the non-transmissive area; and
at least one first optical pattern disposed in the transmissive area; and
a plurality of second optical patterns at least partially overlapping with a border area between the at least one first optical pattern and the non-transmissive area.

22. The transparent display panel of claim 21, wherein the plurality of second optical patterns are disposed in a zigzag arrangement or irregularly spaced apart from an edge of the at least one first optical pattern.

23. The transparent display panel of claim 21, wherein a transmittance of at least one of the plurality of second optical patterns is different than a transmittance of at least another one of the plurality of second optical patterns.

24. The transparent display panel of claim 21, wherein at least one of the plurality of second optical patterns at least partially overlaps both of the transmissive area and the non-transmissive area.

25. The transparent display panel of claim 21, wherein the transmissive area has rounded corners or an octagonal shape.
